(19) United States
(12) Patent Application Publication
(10) Pub. No.: US 2019/0229153 A1
(43) Pub. Date: Jul. 25, 2019

(54) SEMICONDUCTOR NANOPARTICLES, AND DISPLAY DEVICE AND OLED DISPLAY DEVICE COMPRISING THE SAME

(71) Applicants: Samsung Display Co., Ltd., Yongin-si (KR); KOREA ADVANCED INSTITUTE OF SCIENCE AND TECHNOLOGY, Daejeon (KR)

(72) Inventors: Kyoungwon PARK, Seoul (KR); Minki NAM, Incheon (KR); Songyi KIM, Suwon-si (KR); Sungwoon KIM, Yongin-si (KR); Sungjun KOH, Bucheon-si (KR); Seongwon MO, Jeonju-si (KR); Dohchang LEE, Daejeon (KR)

(21) Appl. No.: 16/186,404

(22) Filed: Nov. 9, 2018

(30) Foreign Application Priority Data
Jan. 23, 2018 (KR) 10-2018-0008401

(51) Int. Cl. H01L 27/32; C09K 11/70; C09K 11/88; C09K 11/08

(52) U.S. Cl. CPC H01L 27/322; C09K 11/706; B82Y 20/00; C09K 11/0883; H01L 27/3244; C09K 11/883

(57) ABSTRACT

A display device includes semiconductor nanoparticles. An organic light emitting diode (“OLED”) display device includes the semiconductor nanoparticles, a semiconductor particle of the semiconductor nanoparticles including: a core including a compound semiconductor; and a shell surrounding the core. The shell includes a metal oxide (and/or metalloid oxide) having a bandgap of about 3.5 eV or more, and having a sum (ΔE_{CB}+ΔE_{VB}) of a conduction band offset (ΔE_{CB}) with the compound semiconductor included in the core and a valence band offset (ΔE_{VB}) with the compound semiconductor included in the core of about 3 eV or more.

### CROSS-REFERENCE TO RELATED APPLICATION

This application claims priority to and the benefit of Korean Patent Application No. 10-2018-0008401, filed on Jan. 23, 2018, in the Korean Intellectual Property Office (KIPO), the entire content of which is incorporated herein by reference.

### BACKGROUND

### 1. Field

Embodiments of the present disclosure relate to semiconductor nanoparticles, a display device including the semiconductor nanoparticles, and an organic light emitting diode (“OLED”) display device including the semiconductor nanoparticles.

### 2. Discussion of Related Art

In recent times, image display devices such as liquid crystal display (“LCD”) devices, plasma display devices (PDP), electrophoretic display devices, and organic light emitting diode (“OLED”) display devices are being used. For example, LCD devices are most widely used currently in the field of TV. In addition, in recent times, OLED display devices that have high visibility by virtue of its self-emission characteristics have been attracting attention as a next-generation image display device.

In such LCD devices and OLED display devices, color filters are used. For example, in the case of LCD devices, a backlight is used as a light source, liquid crystals are driven electrically to control the amount of light, and the controlled light passes through the color filter to display color images. In addition, in the case of OLED display devices, a color filter is used with OLEDs that emit white light to display color images, as in the LCD devices.

However, when the white light passes through the color filter, the amount of light is reduced and the luminous efficiency is lowered. For example, in the LCD devices, when light emitted from the backlight source passes through a red color filter, a green color filter, and a blue color filter, the amount of light is reduced to about ⅓ by each color filter, such that the luminous efficiency is degraded.

Accordingly, color conversion members using semiconductor nanoparticles have been recently used instead of the other color filters in order to improve color reproducibility while compensating for degradation of luminous efficiency. However, the quantum efficiency of such a color conversion member may be lowered due to oxidation of the semiconductor nanoparticles.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

Embodiments of the present disclosure may be directed to semiconductor nanoparticles excellent in optical and thermal stability and quantum efficiency.

In addition, another embodiment of the present disclosure may be directed to a display device excellent in luminous efficiency and color reproducibility by applying the aforementioned semiconductor nanoparticles.

According to an embodiment, a semiconductor nanoparticle includes: a core including a compound semiconductor; and a shell surrounding the core. The shell includes a metal oxide (and/or metalloid oxide) having a bandgap of about 3.5 eV or more, and having a sum (ΔE_{CB}+ΔE_{VB}) of a conduction band offset (ΔE_{CB}) with the compound semiconductor included in the core and a valence band offset (ΔE_{VB}) with the compound semiconductor included in the core of about 3 eV or more.

According to another embodiment, a display device includes: a display substrate; a light amount control layer disposed on the display substrate; and a color conversion layer disposed on the light amount control layer and including semiconductor nanoparticles. The semiconductor nanoparticle includes: a core including a compound semiconductor; and a shell surrounding the core and including a metal oxide (and/or metalloid oxide). The metal oxide (and/or metalloid oxide) has a bandgap of about 3.5 eV or more, and has a sum (ΔE_{CB}+ΔE_{VB}) of a conduction band offset (ΔE_{CB}) with the compound semiconductor included in the core and a valence band offset (ΔE_{VB}) with the compound semiconductor included in the core of about 3 eV or more.

According to another embodiment, an organic light emitting display device includes: a base substrate; an organic light emitting element disposed on the base substrate; and a color conversion layer disposed on the organic light emitting element and including semiconductor nanoparticles. The semiconductor nanoparticle includes: a core including a compound semiconductor; and a shell surrounding the core and including a metal oxide (and/or metalloid oxide). The metal oxide (and/or metalloid oxide) has a bandgap of about 3.5 eV or more, and has a sum (ΔE_{CB}+ΔE_{VB}) of a conduction band offset (ΔE_{CB}) with the compound semiconductor included in the core and a valence band offset (ΔE_{VB}) with the compound semiconductor included in the core of about 3 eV or more.

The foregoing is illustrative only and is not intended to be in any way limiting. In addition to the illustrative aspects, exemplary embodiments and features described above, further aspects, exemplary embodiments and features will become apparent by reference to the drawings and the following detailed description.

### BRIEF DESCRIPTION OF THE DRAWINGS

A more complete appreciation of the subject matter of the present disclosure will become more apparent by describing in more detail exemplary embodiments thereof with reference to the accompanying drawings, wherein:

FIG. 1 is a cross-sectional view schematically illustrating semiconductor nanoparticles according to a first embodiment of the present disclosure;

FIG. 2 is a cross-sectional view schematically illustrating semiconductor nanoparticles according to a second embodiment of the present disclosure;

FIG. 3 is a cross-sectional view schematically illustrating semiconductor nanoparticles according to a third embodiment of the present disclosure;

FIG. 4 is an exploded perspective view illustrating a display device according to a fourth embodiment of the present disclosure;

FIG. 5 is a plan view illustrating a pixel of the display device illustrated in FIG. 4;

FIG. 6 is a cross-sectional view taken along line I-I′ in FIG. 5;

FIG. 7 is a plan view illustrating an organic light emitting diode (“OLED”) display device according to a fifth embodiment of the present disclosure;

FIG. 8 is a cross-sectional view illustrating the OLED display device taken along line II-II′ in FIG. 7;

FIG. 9 is a cross-sectional view illustrating an OLED display device according to a sixth embodiment of the present disclosure;

FIG. 10 is an XPS spectrum graph of semiconductor nanoparticles of Exemplary embodiment 1;

FIG. 11 is a graph illustrating intensities of light emission with respect to the wavelength of semiconductor nanoparticles prepared in Comparative examples 1 and 2;

FIG. 12 is a graph illustrating intensities of light emission with respect to the wavelength of semiconductor nanoparticles prepared in Exemplary embodiments 1 and 2;

FIG. 13 is a graph illustrating an absolute photoluminescence quantum efficiency (“PL QY”) of the semiconductor nanoparticles of Exemplary embodiment 2 and Comparative example 2;

FIG. 14 is a graph illustrating a remnant PL QY of the semiconductor nanoparticles of Exemplary embodiment 2 and Comparative example 2;

FIG. 15A is a graph illustrating the energy band of semiconductor nanoparticles of Exemplary embodiment 3, and FIG. 15B is a graph illustrating electron and hole cloud distributions of the semiconductor nanoparticles of Exemplary embodiment 3;

FIG. 16A is a graph illustrating the energy band of semiconductor nanoparticles of Exemplary embodiment 4, and FIG. 16B is a graph illustrating electron and hole cloud distributions of the semiconductor nanoparticles of Exemplary embodiment 4; and

FIG. 17A is a graph illustrating the energy band of semiconductor nanoparticles of Comparative example 3, and FIG. 17B is a graph illustrating electron and hole cloud distributions of the semiconductor nanoparticles of Comparative example 3.

### DETAILED DESCRIPTION

Exemplary embodiments will now be described more fully hereinafter with reference to the accompanying drawings. Although the subject matter of the present disclosure may be modified in various suitable manners and has several exemplary embodiments, exemplary embodiments are illustrated in the accompanying drawings and described in the specification. However, the scope of the present disclosure is not limited to the exemplary embodiments and should be construed as including all the changes, equivalents and substitutions included in the spirit and scope of the present disclosure.

In the drawings, thicknesses of a plurality of layers and areas may be illustrated in an enlarged manner for clarity and ease of description thereof. When a layer, area, or plate is referred to as being “on” another layer, area, or plate, it may be directly on the other layer, area, or plate, or intervening layers, areas, or plates may be present therebetween. Conversely, when a layer, area, or plate is referred to as being “directly on” another layer, area, or plate, intervening layers, areas, or plates may be absent therebetween. Further when a layer, area, or plate is referred to as being “below” another layer, area, or plate, it may be directly below the other layer, area, or plate, or intervening layers, areas, or plates may be present therebetween. Conversely, when a layer, area, or plate is referred to as being “directly below” another layer, area, or plate, intervening layers, areas, or plates may be absent therebetween.

The spatially relative terms “below”, “beneath”, “lower”, “above”, “upper” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in the other direction and thus the spatially relative terms may be interpreted differently depending on the orientations.

Throughout the specification, when an element is referred to as being “coupled” or “connected” to another element, the element is “directly coupled” or “directly connected” to the other element, or “electrically coupled” or “electrically connected” to the other element with one or more intervening elements interposed therebetween. It will be further understood that the terms “comprises,” “including,” “includes” and/or “including,” when used in this specification, specify the presence of stated features, integers, steps, operations, elements and/or components, but do not preclude the presence or addition of one or more other features, integers, steps, operations, elements, components and/or groups thereof.

It will be understood that, although the terms “first,” “second,” “third,” or the like may be used herein to describe various elements, these elements should not be limited by these terms. These terms are only used to distinguish one element from another element. Thus, “a first element” discussed below could be termed “a second element” or “a third element,” and “a second element” and “a third element” may be termed likewise without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Some of the parts which are not associated with the description may not be provided or described to facilitate description of embodiments of the present disclosure. Like reference numerals refer to like elements throughout the specification.

### Semiconductor Nanoparticles

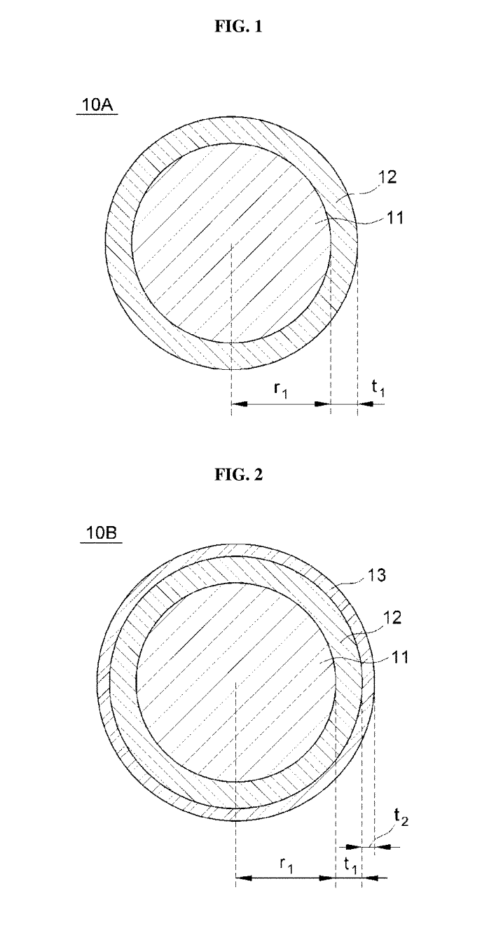

FIGS. 1-3 are cross-sectional views schematically illustrating semiconductor nanoparticles according to first, second, and third embodiments of the present disclosure.

Semiconductor nanoparticles 10A, 10B and 10C according to embodiments of the present disclosure are wavelength converting particles capable of changing the wavelength of incident light incident to the particle. The semiconductor nanoparticle includes a core 11 including a compound semiconductor and a shell 12 surrounding the core 11. The shell 12 includes a metal oxide (and/or metalloid oxide) that has a bandgap of about 3.5 eV or more, and has a sum (ΔE_{CB}+ΔE_{VB}) of a conduction band offset (ΔE_{CB}) with the compound semiconductor included in the core and a valence band offset (ΔE_{VB}) with the compound semiconductor included in the core of about 3 eV or more. With such a structure in which not only the core 11 is protected by the shell 12 but also electron and hole clouds are confined within the core 11 by the shell 12, the semiconductor nanoparticles 10A, 10B and 10C may exhibit high photoluminescence quantum efficiency, and excellent optical and thermal stability. Accordingly, the semiconductor nanoparticles according to embodiments of the present disclosure may improve the photoluminescence quantum efficiency and color reproducibility of a display device.

Hereinafter, semiconductor nanoparticles according to a first embodiment of the present disclosure will be described with reference to FIG. 1.

As illustrated in FIG. 1, the semiconductor nanoparticle 10A according to a first embodiment of the present disclosure includes the core 11 including a compound semiconductor, and the shell 12 surrounding the core 11.

The core 11 includes a compound semiconductor. The compound semiconductors applicable to the present disclosure are not particularly limited and can be any suitable compound semiconductor available in the art. The compound semiconductor may be a semiconductor material including two or more kinds of elements selected from the group consisting of: group II, group III, group IV, group V, and group VI elements on the periodic table. Examples of the compound semiconductor may include group IV compound semiconductors, group II-VI compound semiconductors, group II-V compound semiconductors, group III-V compound semiconductors, group III-VI compound semiconductors, group IV-VI compound semiconductors, and group II-III-V compound semiconductors, but embodiments are not limited thereto. In such an embodiment, each of the compound semiconductors may be a binary compound semiconductor, a ternary (e.g., tertiary) compound semiconductor, or a quaternary compound semiconductor. For example, the compound semiconductor may be: binary compounds such as GaN, GaP, GaAs, GaSb, AlN, AlP, AlAs, AlSb, InN, InP, InAs, InSb, ZnS, ZnSe, ZnTe, CdS, CdSe, or CdTe; ternary (e.g., tertiary) compounds such as GaNP, GaNAs, GaNSb, GaPAs, GaPSb, AlNP, AlNAs, AlNSb, AlPAs, AlPSb, InNP, InNAs, InNSb, InPAs, InPSb, GaAlNP, AlGaN, AlGaP, AlGaAs, AlGaSb, InGaN, InGaP, InGaAs, InGaSb, AlInN, AlInP, AlInAs, or AlInSb; or quaternary compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, but embodiments are not limited thereto. According to one example, the core may include a group III-V compound semiconductor, for example, InP. According to another example, the core may include a group III-II-V compound semiconductor, for example, InZnP and AlInP.

A diameter of such a core is not particularly limited, and may be, for example, in a range of about 1 nm to about 20 nm, for example, in a range of about 2 nm to about 10 nm.

The shape of the core is not particularly limited, and may have, for example, a spherical shape, a rod shape, a disk shape, or the like. The shape of the semiconductor nanoparticle may vary depending on the shape of the core.

In the semiconductor nanoparticles according to an embodiment of the present disclosure, the shell 12 includes a metal oxide (and/or metalloid oxide). In such an embodiment, the metal oxide (and/or metalloid oxide) has a band gap of about 3.5 eV or more, for example, in a range of about 3.5 eV to about 15 eV, or for example, in a range of about 3.5 eV to about 10 eV. The metal oxide (and/or metalloid oxide) has a sum (ΔE_{CB}+ΔE_{VB}) of a conduction band offset (ΔE_{CB}) with the compound semiconductor included in the core and a valence band offset (ΔE_{VB}) with the compound semiconductor included in the core of about 3 eV or more, for example, in a range of about 3 eV to about 15 eV, or for example, in a range of about 3 eV to about 10 eV. The shell 12 including such a metal oxide (and/or metalloid oxide) may confine electron and hole clouds of the core 11 within the core 11, so that the electrons and the holes are more stable in the core 11. Accordingly, the electron and hole clouds in the core are not brought into contact with the outside, and thus the quantum efficiency of the semiconductor nanoparticles 10A according to an embodiment of the present disclosure may be enhanced. In addition, even if an outer surface of the semiconductor nanoparticle 10A is oxidized or quenched, the core of the semiconductor nanoparticle 10A may be protected by the shell. Accordingly, the semiconductor nanoparticles 10A according to an embodiment of the present disclosure have high quantum efficiency and excellent thermal and optical stability. In such an embodiment, the conduction band offset (ΔE_{CB}) is a difference (|E_{CB1}−E_{CB2}|) between a conduction band E_{CB1} of the compound semiconductor included in the core and a conduction band E_{CB2} of the metal oxide (and/or metalloid oxide) included in the shell, and the valence band offset (ΔE_{VB}) is a difference (|E_{VB1}−E_{VB2}|) between a valence band E_{VB1} of the compound semiconductor included in the core and a valence band E_{VB2} of the metal oxide (and/or metalloid oxide) included in the shell. As used herein, the metal oxide (and/or metalloid oxide) is at least one selected from the group consisting of metalloid oxides and metal oxides.

The metal oxide (and/or metalloid oxide) applicable to the present disclosure is not particularly limited and can be any suitable metal oxide and/or metalloid oxide available in the art. For example, a compound including oxygen and at least one element selected from the group consisting of: metalloids, alkaline earth metals, and transition metals, for example, Al₂O₃, SiO₂, TiO₂, MgO, ZnO or the like, but embodiments are not limited thereto. According to an embodiment of the present disclosure, a metal oxide (or metalloid oxide) having a sum of a conduction band offset (ΔE_{CB}) with the compound semiconductor included in the core and a valence band offset (ΔE_{VB}) with the compound semiconductor included in the core in the above range, and a bandgap in the above range is used in the present embodiment by way of example.

For example, the core may include InP, and the shell may include Al₂O₃. In such an embodiment, InP has a conduction band of about −4.5 eV and a valence band of about −5.7 eV, and Al₂O₃ has a conduction band of about −1.3 eV, a valence band of about −9 eV, and a band gap of about 7.7 eV. As such, since the conduction band offset (ΔE_{CB}) and the valence band offset (ΔE_{VB}) between InP and Al₂O₃ are relatively large, each in the ranges of about 3.2 eV and about 3.3 eV, respectively, and since the band gap of Al₂O₃ is as wide as about 7.7 eV, electrons and holes in the core may not be transferred to the outside because of the shell.

The shell 12 may have a single layer structure or a multilayer structure. When the shell has a plurality of layers, each layer may include different metal oxides (and/or metalloid oxides). In such an embodiment, the different metal oxides (or metalloid oxides) may each include metal oxides (or metalloid oxides) that are different from each other, or include metal oxides (or metalloid oxides) of a same kind but having different element ratios. For example, each layer of the shell having two or more layers is formed at a different element ratio. In such an embodiment, an element ratio of each layer may gradually increase or decrease, so that the shell may have a concentration gradient. In such a shell 12, a content of the metal oxide (or metalloid oxide) increases continuously from a boundary with the core toward a surface of the shell.

A thickness of the shell is not particularly limited, but electron and hole clouds may not be confined within the core when the thickness of the shell is too thin as compared with a radius of the core. Accordingly, the thickness of the shell is adjusted in consideration of the radius of the core. For example, a ratio t₁/r₁ of the thickness t₁ of the shell to the radius r₁ of the core may be in a range of about 0.05 to about 5, for example, in a range of about 0.1 to about 5 (see FIG. 1).

It is appropriate that a lattice constant of the shell have a small difference with respect to a lattice constant of the core. For example, a lattice constant difference

$$( \frac{{L}_{1} - {L}_{2}}{{L}_{1}} \times 100 ,$$

L₁ being the lattice constant of the core and L₂ being the lattice constant of the shell) between the shell and the core may be in a range of about −30% to about +30%. When the lattice constant difference between the shell and the core is in the above range, lattice stress may be small, and thus lattice mismatches may be reduced at the core and shell interface, thereby substantially minimizing or reducing the decrease in optical stability and quantum efficiency.

The interface between the core and the shell described above is an area that includes the compound semiconductor included in the core and the metal oxide (or metalloid oxide) included in the shell, and an alloy including the compound semiconductor and the metal oxide (or metalloid oxide) may be formed at the interface between the core and the shell. In such an embodiment, the content of the compound semiconductor continuously decreases from the interface between the core and the shell to the surface of the shell, while the content of the metal oxide (or metalloid oxide) increases continuously from the interface between the core and the shell to the surface of the shell. As such, since the compound semiconductor and the metal oxide (or metalloid oxide) have a concentration gradient, the lattice mismatches are substantially minimized or reduced at the interface between the core and the shell and the shell is uniformly formed (e.g., substantially uniformly formed), and thus the semiconductor nanoparticles according to an embodiment of the present disclosure may be excellent in optical stability and quantum efficiency.

A size (e.g., particle diameter) of the semiconductor nanoparticles is not particularly limited. However, depending on the size and composition of the semiconductor nanoparticles, which are wavelength converting particles capable of changing the wavelength of incident light, the wavelengths that may be converted by the semiconductor nanoparticles may vary. Accordingly, the particle diameter of the semiconductor nanoparticles is controlled within a range of about 1 nm to about 20 nm for the semiconductor nanoparticle to emit a light of a desired color. For example, when the core of the semiconductor nanoparticle including CdSe has a particle diameter ranging from about 2.5 nm to about 3 nm, the core of the semiconductor nanoparticle may emit a light having a wavelength in a range of about 500 nm to about 550 nm, and when the core of the semiconductor nanoparticle including CdSe has a particle diameter ranging from about 3.5 nm to about 4 nm, the core of the semiconductor nanoparticle may emit a light having a wavelength in a range of about 580 nm to about 650 nm.

The semiconductor nanoparticle according to a first embodiment of the present disclosure may be manufactured by any suitable method available in the art, such as, for example, a chemical wet process. The chemical wet method is a method in which a precursor material is added to an organic solvent so that particles may grow. For example, in an organic solvent, a precursor including a group III element and a precursor including a group V element are reacted to form a core including a group III-V compound semiconductor, and then a metal oxide (or metalloid oxide) precursor is added thereto to form a shell including the metal oxide (or metalloid oxide) on a surface of the core, thereby obtaining semiconductor nanoparticles.

As described above, the shell 12 may not only protect the core 11 but also confine electron and hole clouds in the core 11. Accordingly, the quantum efficiency, and the optical and thermal stability of the semiconductor nanoparticles 10A according to an embodiment of the present disclosure may be improved. Such semiconductor nanoparticles of the present disclosure may be applied to various fields such as a display, a solar cell, a biomarker, and a sensor. For example, the semiconductor nanoparticles, wavelength converting particles capable of changing the wavelength of incident light incident to the particles, of the present disclosure may be used as a material for a color conversion layer of a display or the like as. In addition, the semiconductor nanoparticles of the present disclosure may be used as a material for a light emitting layer in organic light emitting diode (“OLED”) display devices.

Hereinafter, semiconductor nanoparticles according to a second embodiment of the present disclosure will be described with reference to FIG. 2.

A semiconductor nanoparticle 10B according to a second embodiment of the present disclosure includes a core 11 including a compound semiconductor; a shell (hereinafter, “a first shell”) 12 surrounding the core, and a second shell 13 surrounding the first shell.

The description of the core 11 and the first shell 12, the size and manufacturing method of the semiconductor nanoparticle, or the like are substantially the same as those described in the first embodiment, and thus repeated description thereof will not be provided here.

The second shell 13 includes a second compound semiconductor which is different from a compound semiconductor included in the core (hereinafter, “first compound semiconductor”). Since the second shell surrounds a surface of the first shell, electrons and holes may be more stably held in the core by the second shell, and an excitation light absorption rate may be increased by the second shell. Accordingly, the semiconductor nanoparticle according to the present embodiment may further improve the optical stability and the quantum efficiency.

The second compound semiconductor is not particularly limited as long as the kind of elements and/or a ratio of the elements included in the second compound semiconductor are different from those included in the first compound semiconductor of the core. For example, the second compound semiconductor may include group II-IV compound semiconductors, for example, ZnS, CdS, PbS, CdSe, ZnSe, PbSe, ZnTe, PbTe, CdTe, ZnSeS, ZnSeTe, ZnSTe, CdZnS, CdZnSe, CdZnTe, CdSeS, CdSeTe, CdSTe, CdZnTeSe, CdZnSSe, or the like, but embodiments are not limited thereto. According to one example, the second compound semiconductor may include ZnSeS. According to another example, the second compound semiconductor may include ZnS.

It is appropriate that an energy bandgap of such a second compound semiconductor be wider than an energy band gap of the first compound semiconductor included in the core by about 0.5 eV to about 4 eV. When the energy band gap of the second compound semiconductor has the above range, the semiconductor nanoparticles may have excellent optical stability and photoluminescence quantum efficiency.

The second shell 13 may have a single layer structure or a multilayer structure. When the second shell 13 has a plurality of layers, each layer may include different second compound semiconductors. In such an embodiment, the different compound semiconductors may include compound semiconductors that are different from each other, or include compound semiconductors of a same kind but having different element ratios. For example, each layer of the second shell having two or more layers is formed at a different element ratio. In such an embodiment, the element ratio of each layer may gradually increase or decrease, so that the second shell may have a concentration gradient. As one example, the second shell may include a ZnSeS layer and a ZnS layer. As another example, the second shell may include a plurality of layers including ZnSeS. In such an embodiment, each layer may have a concentration gradient in which the concentration of S gradually increases from the boundary with the first shell to a surface of the second shell as compared to Se, and an outermost layer of the second shell may be a ZnS layer.

A thickness of the second shell is not particularly limited. In such an embodiment, the thickness of the second shell is adjusted in consideration of a radius of the core or a thickness of the first shell. For example, when a ratio [(t₁+t₂)/r₁] of a total thickness (t₁+t₂) of the first shell and the second shell to the radius r₁ of the core is in a range of about 0.3 to about 10 (for example, in a range of about 0.3 to about 5), a ratio (t₁/t₂) of the thickness t₁ of the first shell to the thickness t₂ of the second shell may be in a range of about 0.1 to about 5 (for example, in a range of about 0.3 to about 5) (see FIG. 2). As such, when the ratio of the thickness of the second shell is relatively small, and the ratio of the thickness of the first shell is relatively large, with respect to the total thickness of the entire shell, the lattice mismatches are reduced by the second shell with the effects of confining electrons and holes by the first shell, and thus the semiconductor nanoparticles of the present disclosure may have excellent optical stability and photoluminescence quantum efficiency.

It is appropriate that a lattice constant of the second shell have a small difference as compared with a lattice constant of the first shell. For example, a lattice constant difference

$$( \frac{{L}_{2} - {L}_{3}}{{L}_{2}} \times 100 ,$$

L₂ being the lattice constant of the first shell and L₃ being the lattice constant of the second shell) between the second shell and the first shell may be in a range of about −30% to about +30%. When the lattice constant difference between the second shell and the first shell is in the above range, the lattice mismatches between the first shell and the second shell may be substantially minimized or reduced to stabilize an interface therebetween, and the decrease in the luminous stability and the photoluminescence quantum efficiency may be substantially minimized or reduced.

However, when the lattice constant difference between the core and the first shell is large, it is appropriate that the lattice constant of the second shell have a small difference as compared to the lattice constant of the core. For example, when the lattice constant difference between the core and the first shell

$$( \frac{{L}_{1} - {L}_{2}}{{L}_{1}} \times 100 ,$$

L₁ being the lattice constant of the core and L₂ being the lattice constant of the first shell) is in a range of about −30% to about 30%, the lattice constant difference between the second shell and the core

$$( \frac{{L}_{1} - {L}_{3}}{{L}_{1}} \times 100 ,$$

L₁ being the lattice constant of the core and L₃ being the lattice constant of the second shell) may be in a range of about −30% to about 30%. For example, in the semiconductor nanoparticles having a sandwich structure in which the first shell is sandwiched between the core and the second shell, the lattice constant difference between the core and the first shell becomes small as the lattice constant of the first shell becomes small by the core and the second shell. Accordingly, as the lattice stress in the semiconductor nanoparticles is reduced, each interface is stabilized, and accordingly the decrease in the optical stability and the photoluminescence quantum efficiency may be substantially minimized or reduced.

The interface between the first shell and the second shell is an area that includes the metal oxide (or metalloid oxide) included in the first shell and the second compound semiconductor included in the second shell. An alloy of the metal oxide (or metalloid oxide) and the second compound semiconductor is formed at the interface, and the lattice mismatches between the first shell and the second shell may be substantially minimized or reduced. Accordingly, the semiconductor nanoparticles according to the present disclosure may improve the optical stability and the luminous efficiency.

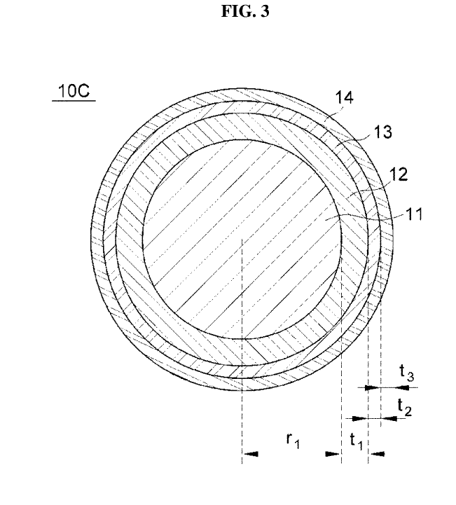

Hereinafter, semiconductor nanoparticles according to a third embodiment of the present disclosure will be described with reference to FIG. 3.

A semiconductor nanoparticle 10C according to a third embodiment of the present disclosure includes a core 11 including a compound semiconductor; a shell (hereinafter, “a first shell”) 12 surrounding the core, a second shell 13 surrounding the first shell 12, and a third shell 14 surrounding the second shell 13, as illustrated in FIG. 3.

The descriptions of the core and the first shell are the same as those described in the first embodiment of the present disclosure, and the descriptions of the second shell are the same as those described in the second embodiment of the present disclosure, and repeated description thereof will not be repeated here.

The third shell 14 is a portion surrounding the second shell. The third shell 14 may have a single layer structure or a multilayer structure. The third shell 14 may include a second metal oxide (and/or metalloid oxide) which is substantially the same as or different from the metal oxide (and/or metalloid oxide) included in the first shell (hereinafter, “first metal oxide (and/or metalloid oxide)”.

Similar to the metal oxide (and/or metalloid oxide) described in the first embodiment, the second metal oxide (and/or metalloid oxide) applicable to the present embodiment may be a compound including oxygen and at least one element selected from the group consisting of metalloids, alkaline earth metals, and transition metals, for example, Al₂O₃, SiO₂, TiO₂, MgO, ZnO or the like, but embodiments are not limited thereto.

A thickness of the third shell is not particularly limited, and may be in a range of about 0.5 nm to about 5 nm. In such an embodiment, the thickness of the third shell is adjusted in consideration of a radius of the core or a thickness of each shell. For example, when a ratio [(t₁+t₂+t₃)/r₁] of a total thickness (t₁+t₂+t₃) of the first shell, the second shell, and the third shell to the radius r₁ of the core is in a range of about 0.1 to about 10, a ratio [(t₁+t₃)/t₂)] of a total thickness (t₁+t₃) of the first shell and the third shell to the thickness t₂ of the second shell may be in a range of about 0.3 to about 5, and in such an embodiment, a ratio (t₁/t₃) of the thickness t₁ of the first shell to the thickness t₃ of the third shell may be in a range of about 0.1 to about 5 (see FIG. 3). As such, when the ratio of the thickness of the second shell is relatively small, and the ratio of the thickness of the first shell is relatively large, with respect to the total thickness of the entire shell, the lattice mismatches are reduced by the second shell with the effects of confining electrons and holes by the first shell, and thus the semiconductor nanoparticles of the present disclosure have excellent optical stability and photoluminescence quantum efficiency.

### Display Device

In an embodiment, the present disclosure provides a display device using the semiconductor nanoparticles 10A, 10B, and 10C.

As described above, with such a structure in which not only the core 11 is protected by the shell 12 but also the electron and hole clouds are confined within the core 11 by the shell 12, the semiconductor nanoparticles 10A, 10B and 10C may exhibit high photoluminescence quantum efficiency, and excellent optical and thermal stability. The display device using such semiconductor nanoparticles has excellent luminous efficiency and excellent color rendering capability.

A display device 101 according to an embodiment of the present disclosure includes a display substrate 110; a light amount control layer 120 disposed on the display substrate 110, and a color conversion layer 132 disposed on the light amount control layer 120. In such an embodiment, the color conversion layer 132 includes semiconductor nanoparticles, and the semiconductor nanoparticles may be at least one type selected from the semiconductor nanoparticles described in the first, second, and third embodiments.

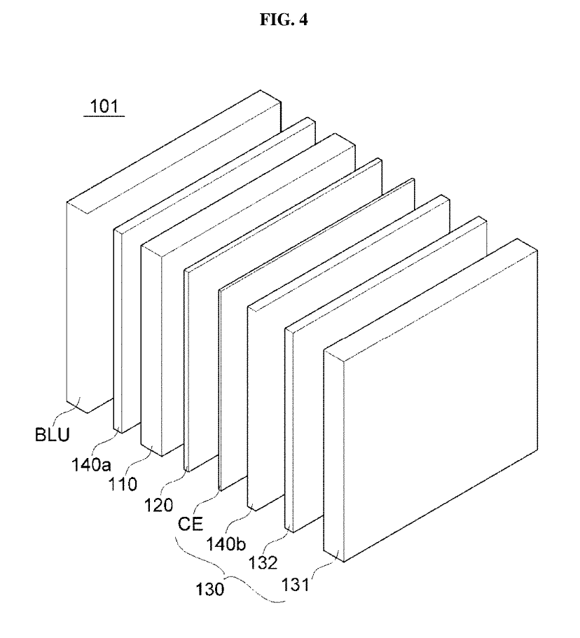

Hereinafter, a display device according to a fourth embodiment of the present disclosure will be described with reference to FIGS. 4-6.

FIG. 4 is an exploded perspective view illustrating a display device according to a fourth embodiment of the present disclosure.

Referring to FIG. 4, a display device according to a fourth embodiment of the present disclosure includes a backlight unit BLU, a first polarizer 140a, a display substrate 110, a light amount control layer 120, and an opposing substrate 130 which are sequentially stacked. The opposing substrate 130 includes a common electrode CE, a second polarizer 140b, a color conversion layer 132, and a second substrate 131.

The backlight unit BLU may emit ultraviolet light, near ultraviolet light, or the like. The backlight unit BLU may, for example, emit white light or blue light to the display panel DP. Hereinafter, a fourth embodiment will be described with respect to a display device including a backlight unit BLU that emits blue light.

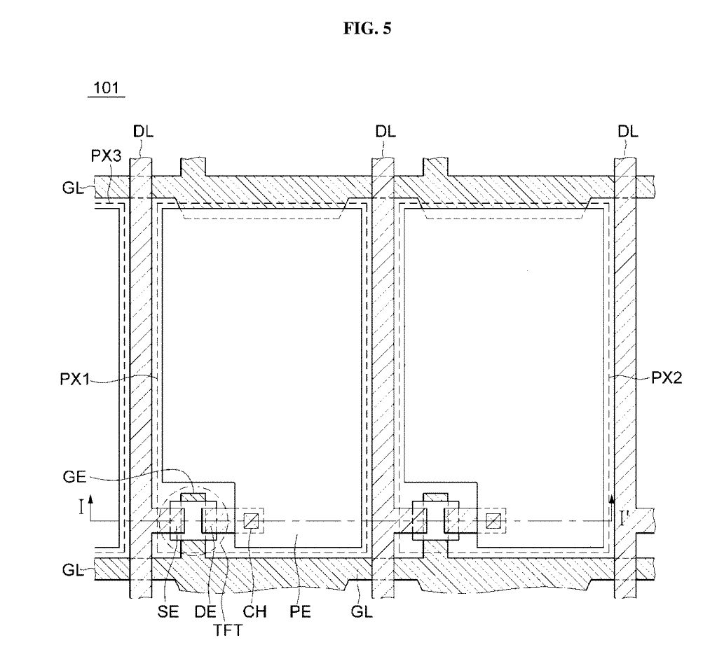

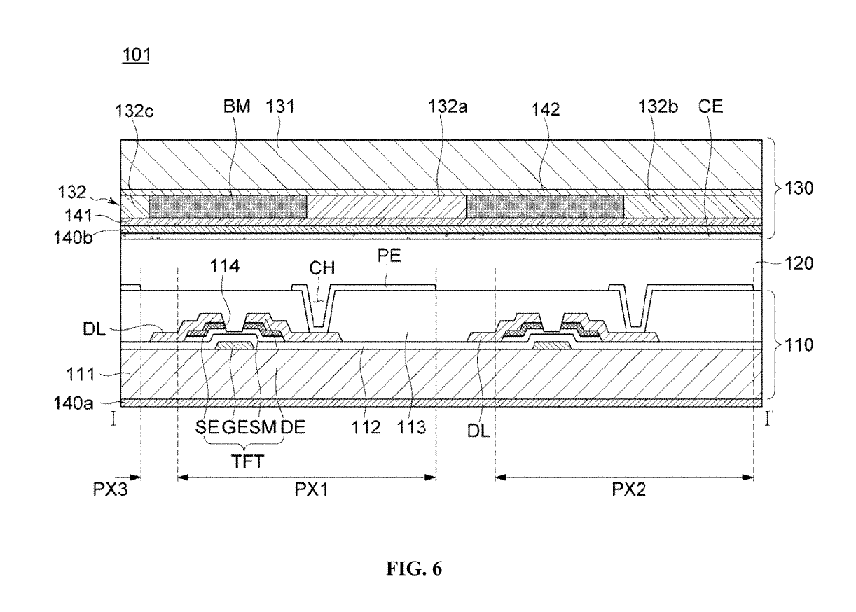

FIG. 5 is a plan view illustrating a pixel of the display device illustrated in FIG. 4, and FIG. 6 is a cross-sectional view taken along line I-I′ in FIG. 5.

As illustrated in FIGS. 5 and 6, the display device 101 includes the display substrate 110, the opposing substrate 130 opposing the display substrate 110, and the light amount control layer 120 disposed between the display substrate 110 and the opposing substrate 130. In such an embodiment, an adhesive layer (not illustrated) may be disposed between each element.

The light amount control layer 120 is disposed on the display substrate 110. The light amount control layer 120 may use any suitable layer available in the art that may control transmittance of light provided from the backlight unit BLU. For example, the light amount control layer 120 may be one of a liquid crystal layer, an electro-wetting layer, and an electrophoresis layer. Hereinafter, the light amount control layer 120 will be described on the premise that it is a liquid crystal layer by way of example. In such an embodiment, the display device 101 according to a fourth embodiment of the present disclosure may be referred to as an LCD device.

The display substrate 110 includes a first substrate 111, a thin film transistor TFT, a pixel electrode PE, a gate insulating layer 112, and a protective layer 113.

The thin film transistor TFT is disposed on the first substrate 111, and includes a semiconductor layer SM, an ohmic contact layer 114, a gate electrode GE, a source electrode SE, and a drain electrode DE.

The first substrate 111 includes a transparent material such as glass or plastic.

A plurality of gate lines GL and a plurality of gate electrodes GE are disposed on the first substrate 111. The gate electrode GE and the gate line GL are formed unitarily. The gate line GL and the gate electrode GE may include or be formed of aluminum-base metal (e.g., aluminum (Al) or alloys thereof), silver-based metal (e.g., silver (Ag) or alloys thereof), copper-based metal (e.g., copper (Cu) or alloys thereof), molybdenum-based metal (e.g., molybdenum (Mo) or alloys thereof), chromium (Cr), tantalum (Ta) and titanium (Ti). At least one of the gate line GL and the gate electrode GE may have a multilayer structure including at least two conductive layers that have different physical properties from each other.

The gate insulating layer 112 is disposed over the entire surface of the first substrate 111 including the gate line GL and the gate electrode GE. The gate insulating layer 112 may include silicon nitride (SiNx), silicon oxide (SiOx), or the like. In addition, the gate insulating layer 112 may have a multilayer structure including at least two insulating layers having different physical properties.

The semiconductor layer SM is disposed on the gate insulating layer 112. In such an embodiment, the semiconductor layer SM overlaps the gate electrode GE located below the gate insulating layer 112. The semiconductor layer SM may include or be formed of amorphous silicon, polycrystalline silicon, or the like. In addition, the semiconductor layer SM may include an oxide semiconductor.

The ohmic contact layer 114 is disposed on the semiconductor layer SM. For example, the ohmic contact layer 114 is disposed on the semiconductor layer SM other than a channel portion thereof.

In addition, a plurality of data lines DL are disposed on the gate insulating layer 112. The data lines DL intersect the gate lines GL. The source electrode SE is formed unitarily with the data line DL. The source electrode SE is disposed on the ohmic contact layer 114. The drain electrode DE is disposed on the ohmic contact layer 114 and coupled to (e.g., connected to) the pixel electrode PE.

At least one of the data line DL, the source electrode SE, and the drain electrode DE may include or be formed of a refractory metal, such as molybdenum, chromium, tantalum, titanium, and/or an alloy thereof. In addition, at least one of the data line DL, the source electrode SE, and the drain electrode DE may have a multilayer structure including a refractory metal layer and a low resistance conductive layer.

The protective layer 113 is disposed over the entire surface of the first substrate 111 including the semiconductor layer SM, the data line DL, the source electrode SE, and the drain electrode DE. The protective layer 113 may include or be formed of an inorganic insulating material, e.g., silicon nitride (SiNₓ) or silicon oxide (SiOₓ). Alternatively, the protective layer 113 may include an organic layer. The protective layer 113 may have a double-layer structure including a lower inorganic layer and an upper organic layer.

The pixel electrode PE is disposed on the protective layer 113. In such an embodiment, the pixel electrode PE is coupled to (e.g., connected to) the drain electrode DE through a contact hole CH of the protective layer 113. The pixel electrode PE may include a transparent conductive material such as indium tin oxide (ITO) or indium zinc oxide (IZO).

The first polarizer 140a is disposed on the display substrate 110. For example, the first polarizer 140a may be disposed on a back surface of the first substrate 111.

Referring to FIG. 6, the opposing substrate 130 includes the second substrate 131, the color conversion layer 132, the second polarizer 140b, and the common electrode CE. According to a fourth embodiment of the present disclosure, the opposing substrate 130 further includes a light blocking layer BM.

For example, in the opposing substrate 130, the common electrode CE is disposed on the light amount control layer 120, the second polarizer 140b is disposed on the common electrode CE, the color conversion layer 132 is disposed on the second polarizer 140b, and the second substrate 131 is disposed on the color conversion layer 132.

The second substrate 131 opposes the first substrate 111. The second substrate 131 may include or be formed of a transparent material such as glass or plastic.

The common electrode CE is disposed between the light amount control layer 120 and the second substrate 131. The common electrode CE applies an electric field to the light amount control layer 120 together with the pixel electrodes PE. Accordingly, an electric field is formed in the liquid crystal layer which is the light amount control layer 120 between the common electrode CE and the pixel electrode PE. The common electrode CE may include a transparent conductive material such as ITO or IZO.

The second polarizer 140b may be disposed between the light amount control layer 120 and the second substrate 131, for example, between the common electrode CE and the color conversion layer 132. A transmission axis of the second polarizer 140b is substantially orthogonal to a transmission axis of the first polarizer 140a, and one of these transmission axes may be arranged in parallel (e.g., substantially in parallel) with the gate line GL. A first passivation layer 141 may be disposed between the second polarizer 140b and the color conversion layer 132, and a second passivation layer 142 may be disposed between the color conversion layer 132 and the second substrate 131.

The light blocking layer BM is disposed between the second substrate 131 and the common electrode CE. The light blocking layer BM has a plurality of openings. The openings are located corresponding to each pixel electrode PE of first and second pixels PX1 and PX2. The light blocking layer BM blocks light in portions other than the openings. For example, the light blocking layer BM is disposed on the thin film transistors TFT, the gate line GL, and the data line DL to block light that has passed through them from being emitted to the outside. The light blocking layer BM is not invariably necessary, and may be omitted.

The color conversion layer 132 is disposed on the second substrate 131, for example, between the common electrode CE and the second substrate 131. The conversion layer 132 converts the wavelength of light incident thereto from the backlight unit BLU, and emits light having a different wavelength. The color conversion layer 132 includes the semiconductor nanocrystals according to the present disclosure.

For example, the color conversion layer 132 includes a plurality of color converters 132a and 132b. As illustrated in FIG. 6, the color conversion layer 132 includes a first color converter 132a and a second color converter 132b. In such an embodiment, each of the color converters 132a and 132b may be separated by the light blocking layer BM.

Each of the color converters 132a and 132b is disposed so as to overlap pixels PX1 and PX2. For example, each of the color converters 132a and 132b may be located at an opening of the light blocking layer BM corresponding to the pixel electrode PE. In addition, the respective color converters 132a and 132b correspond to the respective pixels PX1 and PX2. For example, the first color converter 132a may correspond to a red pixel PX1, and the second color converter 132b may correspond to a green pixel PX2. For example, the first color converter 132a emits red light, and the second color converter 132b emits green light.

Each of the color converters 132a and 132b includes a resin and semiconductor nanocrystals 10 dispersed in the resin. The semiconductor nanocrystals 10 are at least one selected from the semiconductor nanoparticles 10A, 10B, and 10C described in the first, second, and third embodiments, and descriptions thereof are substantially the same as those described in the first, second, and third embodiments, and repeated description thereof will not be provided here. Such a semiconductor nanocrystal absorbs light having a set or predetermined wavelength and emits light having a different wavelength. For example, the first color converter 132a includes semiconductor nanocrystals that absorb blue light and emit red light, and the second color converter 132b includes semiconductor nanocrystals that absorb blue light and emit green light. In such an embodiment, since the wavelength to be converted varies depending on the size (for example, particle size) of the semiconductor nanocrystals, the semiconductor nanocrystals adjust the size thereof to emit light of a desired color. The display device 101 according to an embodiment of the present disclosure including the color converters 132a and 132b that include such semiconductor nanocrystals has high luminous efficiency and excellent color rendering capability.

In addition, the color converters 132a and 132b may further include a reflector. Examples of the reflectors may include, but are not limited to, TiO₂. The reflector may have a particle shape, and may be dispersed in the resin together with the semiconductor nanocrystals.

Although not illustrated, the color conversion layer 132 may further include a third color converter that absorbs blue light and emits light other than red and green.

The color conversion layer 132 includes a transmissive portion 132c. The wavelength of light that passes through the transmissive portion 132c does not change. When the backlight unit BLU emits blue light, the transmissive portion 132c corresponds to a blue pixel PX3.

### Organic Light Emitting Display Device

In an embodiment, the present disclosure provides an OLED display device using the semiconductor nanocrystals 10A, 10B, and 10C. The OLED display device to which the semiconductor nanocrystals 10A, 10B, and 10C are applied has high luminous efficiency and excellent color rendering capability.

A display device 102 according to the present embodiment includes a base substrate 211, an OLED 310 on the base substrate 211, and a color conversion layer 320 on the OLED 310. The color conversion layer 320 includes semiconductor nanoparticles, and the semiconductor nanoparticles may be at least one type selected from the semiconductor nanoparticles described in the first, second, and third embodiments.

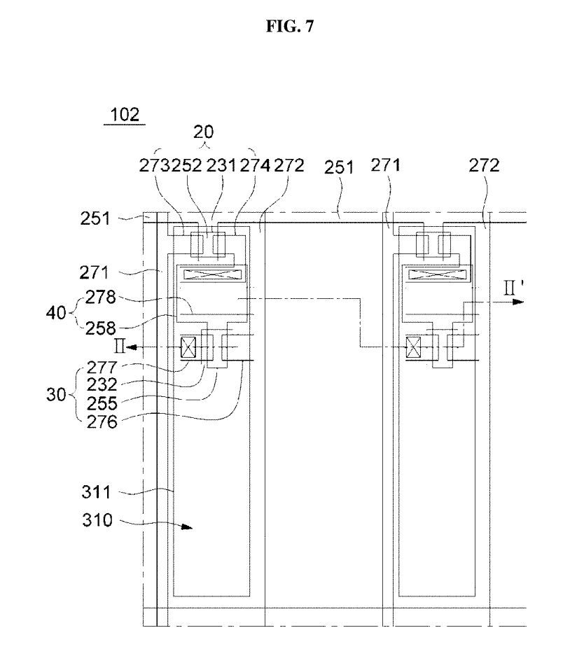

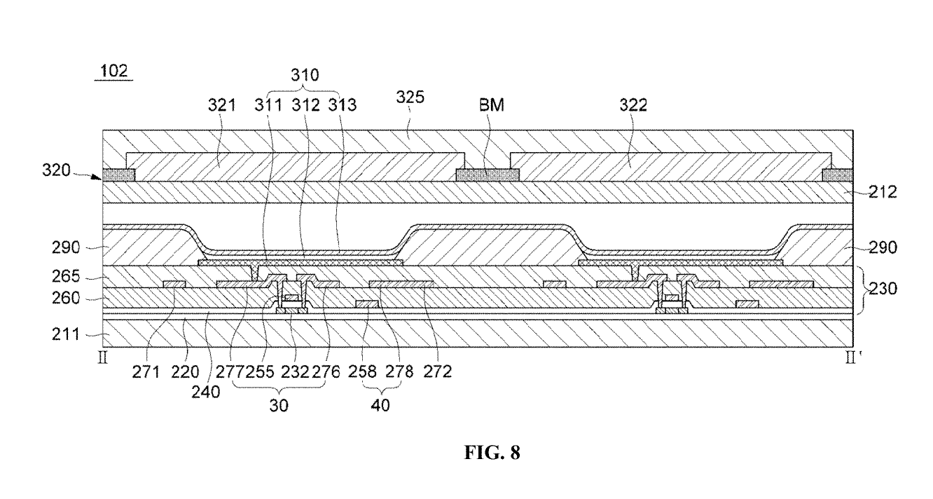

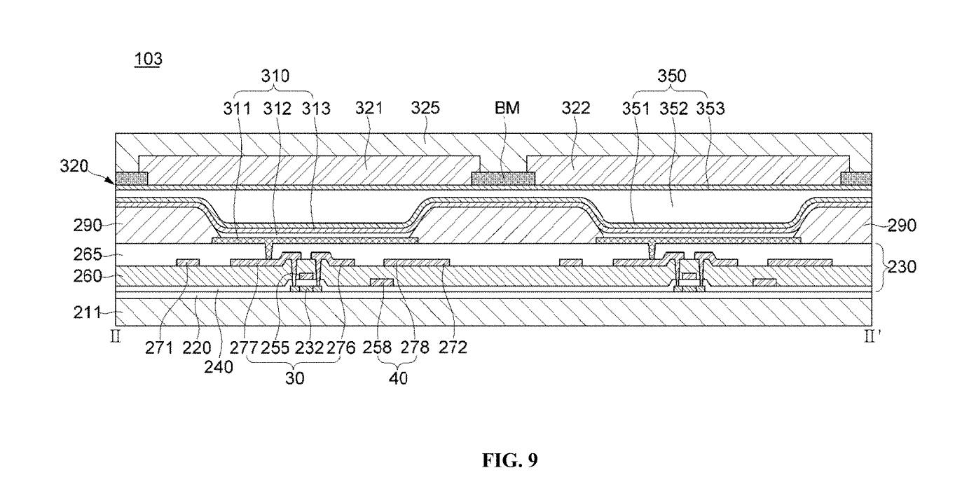

Hereinafter, an OLED display device according to a fifth embodiment will be described with reference to FIGS. 7-8.

FIG. 7 is a plan view illustrating an organic light emitting diode (“OLED”) display device according to a fifth embodiment of the present disclosure, and FIG. 8 is a cross-sectional view illustrating the OLED display device taken along line II-II′ in FIG. 7.

For example, the OLED display device 102 according to a fifth embodiment includes the base substrate 211, a driving circuit unit 230, and the OLED 310.

The base substrate 211 may include or be formed of an insulating material such as glass, quartz, ceramics, plastic, or the like. In addition, a polymer film may be used as the base substrate 211.

A buffer layer 220 may be further disposed on the base substrate 211. The buffer layer 220 may include one or more layers selected from various suitable inorganic layers and organic layers. The buffer layer 220 may be omitted.

The driving circuit unit 230 is disposed on the base substrate 211 (or on the buffer layer 220). The driving circuit unit 230 corresponds to a portion including a plurality of thin film transistors (“TFTs”) 20 and 30 and a capacitor 40, and drives the OLED 310. For example, the OLED 310 emits light according to a driving signal received from the driving circuit unit 230 to display images.

FIGS. 7-8 illustrate an active matrix-type organic light emitting diode (“AMOLED”) display device 102 having a 2Tr-1Cap structure. For example, the 2Tr-1Cap structure may include two TFTs, e.g., a switching TFT 20 and a driving TFT 30, and one capacitor 40 in each pixel, but embodiments are not limited thereto. For example, the OLED display device 102 may include three or more TFTs and two or more capacitors in each pixel, and may further include additional wirings. Herein, the term “pixel” refers to a smallest unit for displaying images, and the OLED display device 102 displays images using a plurality of pixels.

One pixel includes the switching TFT 20, the driving TFT 30, the capacitor 40, and the OLED 310. In addition, a gate line 251 extending in one direction, a data line 271 and a common power line 272 insulated from and intersecting the gate line 251 are also disposed in the driving circuit portion 230. One pixel PX may be defined by the gate line 251, the data line 271 and the common power line 272, in which they become a boundary, but embodiments are not limited thereto. The pixel may be defined by a pixel defining layer 290 or a black matrix.

The switching TFT 20 may serve as a switching element which selects a pixel to perform light emission. The switching TFT 20 includes a switching semiconductor layer 231, a switching gate electrode 252, a switching source electrode 273, and a switching drain electrode 274. In such an embodiment, the switching gate electrode 252 is coupled to (e.g., connected to) the gate line 251, the switching source electrode 273 is coupled to (e.g., connected to) the data line 271, and the switching drain electrode 274 is spaced apart from the switching source electrode 273 and is coupled to (e.g., connected to) one of storage plates of the capacitor 40, e.g., a storage plate 258. The switching semiconductor layer 231 and the switching gate electrode 252 are insulated by a gate insulating layer 240.

The driving TFT 30 applies a driving power to a first electrode 311 which is a pixel electrode. The driving power allows an organic light emitting layer 312 of the OLED 310 in a pixel selected by the switching TFT 20 to emit light. The driving TFT 30 includes a driving semiconductor layer 232, a driving gate electrode 255, a driving source electrode 276, and a driving drain electrode 277. The driving gate electrode 255 is coupled to (e.g., connected to) the storage plate 258 that is coupled to (e.g., connected to) the switching drain electrode 274. The driving source electrode 276 is coupled to (e.g., connected to) the common power line 272, and the common power line 272 is coupled to (e.g., connected to) another storage plate of the capacitor 40, e.g., a storage plate 278. The driving drain electrode 277 is coupled to (e.g., connected to) the first electrode 311 of the OLED 310 through a contact hole defined in a planarization layer 265. The driving semiconductor layer 232 and the driving gate electrode 255 are insulated by the gate insulating layer 240.

The capacitor 40 includes a pair of storage plates 258 and 278 with an insulating layer 260 interposed therebetween. In such an embodiment, the insulating layer 260 may be a dielectric element. A capacitance of the capacitor 40 is determined by electric charges accumulated in the capacitor 40 and a voltage across the pair of storage plates 258 and 278.

With the above described structure, the switching TFT 20 is driven by a gate voltage applied to the gate line 251 and serves to transmit a data voltage applied to the data line 271 to the driving TFT 30. In such an embodiment, a voltage equivalent to a difference between a common voltage applied to the driving TFT 30 from the common power line 272 and the data voltage transmitted from the switching TFT 20 is stored in the capacitor 40, and a current corresponding to the voltage stored in the capacitor 40 flows to the OLED 310 through the driving TFT 30, such that the OLED 310 may emit light.

The OLED 310 is a portion of emitting light according to the driving signal received from the driving circuit 230 to display images. As illustrated in FIG. 8, the OLED 310 includes the first electrode 311, the organic light emitting layer 312, and a second electrode 313 which are sequentially stacked on the base substrate 211.

For example, the organic light emitting layer 312 is a layer in which excitons are formed by combination of holes and electrons injected from the first electrode 311 and the second electrode 313, respectively. The emission color of the OLED (i.e., an organic electroluminescent element) may be changed according to a material forming the light emitting layer. Such a material forming the organic light emitting layer is not particularly limited and may be any suitable substance forming a light emitting layer available in the art. For example, the organic light emitting layer 312 may include a host material such as 4,4′-bis(N-carbazolyl)-1,1′-biphenyl (“CBP”), 4,4′-bis(N-carbazolyl)-1,1′-biphenyl, poly (n-vinylcarbazole) (“PVK”), poly(n-vinylcarbazole), 9,10-di(naphthalene-2-yl)anthracene (“ADN”), or 9,10-di (naphthalen-2-yl) anthracene; and a phosphorescent or fluorescent dopant such as an organometallic complex including Ir, Pt, Os, Re, Ti, Zr, and Hf, or a combination of two or more thereof. However, embodiments are not limited thereto.

Holes and electrons are injected into the organic light emitting layer 312 from the first electrode 311 and the second electrode 313, respectively, and combined therein to form an exciton. Light emission occurs when the exciton falls from an excited state to a ground state.

The first electrode 311 may be a transmissive electrode having light transmittance or a reflective electrode having light reflectance. In addition, the second electrode 313 may include a transflective (semi-transmissive) layer or a reflective layer. For example, the first electrode 311 may be a reflective electrode, and the second electrode 313 may be a transflective electrode. Accordingly, the light generated in the organic light emitting layer 312 is emitted through the second electrode 313. In such an embodiment, the OLED display device 102 according to a fifth embodiment of the present disclosure has a top emission type structure.

One or more metal of magnesium (Mg), silver (Ag), gold (Au), calcium (Ca), lithium (Li), chromium (Cr), aluminum (Al), and copper (Cu), or an alloy thereof may be used to form a transflective electrode and a reflective electrode. In such an embodiment, whether an electrode is a transflective type or a reflective type depends on the thickness of the electrode. For example, the transflective electrode has a thickness of about 200 nm or less. As the thickness of the transflective electrode decreases, light transmittance increases. On the other hand, as the thickness of the transflective electrode increases, light transmittance decreases.

For example, the first electrode 311 may include a reflective layer which includes one or more metal of magnesium (Mg), silver (Ag), gold (Au), calcium (Ca), lithium (Li), chromium (Cr), aluminum (Al), or copper (Cu), and a transparent conductive layer on the reflective layer. In such an embodiment, the transparent conductive layer may include transparent conductive oxide (“TCO”). For example, TCO may include at least one of: indium tin oxide (ITO), indium zinc oxide (IZO), zinc oxide (ZnO), aluminum zinc oxide (AZO) or indium oxide (In₂O₃). Since such a transparent conductive layer has a high work function, the first electrode 311 may inject holes into the organic light emitting layer 312 smoothly.

In addition, the first electrode 311 may have a triple-layer structure in which a transparent conductive layer, a reflective layer and a transparent conductive layer are sequentially stacked.

The second electrode 313 may include a transflective layer which includes one or more metal of magnesium (Mg), silver (Ag), gold (Au), calcium (Ca), lithium (Li), chromium (Cr), aluminum (Al), or copper (Cu).

Although not illustrated in the drawings, at least one of a hole injection layer HIL and a hole transport layer HTL may further be provided between the first electrode 311 and the organic light emitting layer 312. In addition, at least one of an electron transport layer ETL and an electron injection layer EIL may further be provided between the organic light emitting layer 312 and the second electrode 313. In such an embodiment, the organic light emitting layer 312, the hole injection layer HIL, the hole transport layer HTL, the electron transport layer ETL, and the electron injection layer EIL may be referred to as organic layers. Each of the hole injection layer HIL, the hole transport layer HTL, the electron transport layer ETL, and the electron injection layer EIL may be formed using any suitable low molecular weight organic material or any suitable high molecular weight organic material available in the art.

The pixel defining layer 290 has an opening. The opening of the pixel defining layer 290 exposes a portion of the first electrode 311. The organic light emitting layer 312 and the second electrode 313 are sequentially stacked on the first electrode 311 at the opening of the pixel defining layer 290. In such an embodiment, the second electrode 313 is formed on the pixel defining layer 290 as well as on the organic light emitting layer 312. In an embodiment, the hole injection layer HIL, the hole transport layer HTL, the electron transport layer ETL, and the electron injection layer EIL may also be disposed between the pixel defining layer 290 and the second electrode 313. The OLED 310 generates light from the organic light emitting layer 312 located at the opening of the pixel defining layer 290. In such a manner, the pixel defining layer 290 may define a light emission area.

Although not illustrated in the drawing, a capping layer may be disposed on the second electrode 313. The capping layer serves to protect the OLED 310 and allows the light generated in the organic layer to be emitted outside efficiently. For example, the capping layer may substantially prevent or reduce light loss due to total reflection of light in the second electrode in the top emission type OLED display device. Any suitable material available in the art may be used to form such a capping layer without particular limitation.

An encapsulation substrate 212 may be further disposed on the second electrode. The encapsulation substrate 212 serves to seal the OLED 310 together with the base substrate 211. The encapsulation substrate 212, similar to the base substrate 211, may include or be formed of an insulating material selected from the group consisting of: glass, quartz, ceramics, and plastic.

The color conversion layer 320 is disposed on the encapsulation substrate 212. The color conversion layer 320 converts the wavelength of light incident from the OLED 310 to emit light having a different wavelength. According to a fifth embodiment of the present disclosure, the color conversion layer 320 includes the semiconductor nanocrystals according to the present disclosure.

The color conversion layer 320 includes a plurality of color converters 321 and 322. The color converters 321 and 322 include the semiconductor nanocrystals according to the present disclosure that absorb light of a certain wavelength and emit light having a different wavelength. The color converters 321 and 322 may be separated from each other by the light blocking layer BM.

Each of the color converters 321 and 322 is disposed to overlap the organic light emitting layer 312.

According to a fifth embodiment of the present disclosure, the OLED 310 emits blue light. For example, the organic light emitting layer 312 emits blue light.

Referring to FIG. 8, the color conversion layer 320 includes a first color converter 321 and a second color converter 322. For example, the first color converter 321 may correspond to a red pixel, and the second color converter 322 may correspond to a green pixel. For example, the first color converter 321 absorbs blue light to emit red light, and the second color converter 322 absorbs blue light to emit green light. The first color converter 321 includes semiconductor nanocrystals that emit red light, and the second color converter 322 includes semiconductor nanocrystals that emit green light. The semiconductor nanocrystals are at least one of the semiconductor nanocrystals described in the first, second, and third embodiments, and the descriptions thereof are substantially the same as that described in the first, second, and third embodiments, and repeated description thereof will not be provided here.

According to a fifth embodiment of the present disclosure, the color conversion layer 320 may further include a transmissive portion (not illustrated). The wavelength of light passing through the transmissive portion does not change. The transmissive portion may correspond to a blue pixel.

Although not illustrated, the color conversion layer 320 may further include a third color converter that absorbs blue light and emits light other than red and green.

In addition, referring to FIG. 8, a transparent protective layer 325 for protecting the color converters 321 and 322 is disposed on the color conversion layer 320.

FIG. 9 is a cross-sectional view illustrating an OLED display device 103 according to a sixth embodiment of the present disclosure.

The OLED display device 103 according to a sixth embodiment of the present disclosure includes a thin film encapsulation layer 350 disposed on a second electrode 313. Since other structures are substantially the same as those described in the fifth embodiment except for the thin film encapsulation layer 350, and repeated descriptions thereof will not be provided here.

The thin film encapsulation layer 350 is a layer for protecting the OLED 310. The thin film encapsulation layer 350 includes one or more inorganic layers 351 and 353 and one or more organic layers 352, and substantially prevents or reduces outside air such as moisture or oxygen from permeating into the OLED 310.

The thin film encapsulation layer 350 has a structure in which the one or more inorganic layers 351 and 353 and the one or more organic layers 352 are alternately stacked. In FIG. 9, the thin film encapsulation layer 350 includes two inorganic layers 351 and 353 and one organic layer 352, but embodiments are not limited thereto.

The inorganic layers 351 and 353 may include one or more inorganic materials of: Al₂O₃, TiO₂, ZrO, SiO₂, AlON, AlN, SiON, Si₃N₄, ZnO and Ta₂O₅. The inorganic layers 351 and 353 may be formed through methods such as a chemical vapor deposition (CVD) method or an atomic layer deposition (ALD) method. However, embodiments are not limited thereto, and the inorganic layers 351 and 353 may be formed using various suitable methods available in the art.

The organic layer 352 may include a polymer-based material. Examples of the polymer-based material may include, for example, an acrylic resin, an epoxy resin, polyimide, and polyethylene. In addition, the organic layer 352 may be formed through a thermal deposition process. The thermal deposition process may be performed within a temperature range that may not damage the OLED 310. However, embodiments are not limited thereto, and the organic layer 352 may be formed using various suitable methods available in the art.

The inorganic layers 351 and 353 which have a high density of thin layer may prevent or efficiently reduce permeation of, mostly, moisture or oxygen. Permeation of moisture and oxygen into the OLED 310 may be largely prevented or reduced by the inorganic layers 351 and 353. Moisture and oxygen that have passed through the inorganic layers 351 and 353 are blocked again by the organic layer 352. The organic layer 352 has a less effect of preventing or reducing moisture permeation than the inorganic layers 351 and 353. However, the organic layer 350 may also serve as a buffer layer to reduce stress between respective ones of the inorganic layers 351 and 353, in addition to the moisture-permeation preventing or reducing function. In addition, since the organic layer 352 has planarizing characteristics, an uppermost surface of the thin film encapsulation layer 350 may be planarized.

The thin film encapsulation layer 350 may have a small thickness of about 10 μm or less. Accordingly, the OLED display device 103 may also have a small thickness. By applying the thin film encapsulation layer 350 as described above, the OLED display device 103 may have flexible characteristics.

In the case where the thin film encapsulation layer 350 is used in place of the encapsulation substrate 212, which is dissimilar to the fifth embodiment, and further, a flexible substrate is used as the base substrate 211, the OLED display device 103 may serve as a flexible display device.

Hereinafter, the present disclosure will be described in more detail with respect to exemplary embodiments. However, the following exemplary embodiments are given for illustrative purposes only, and the scope of the present disclosure is not limited to these exemplary embodiments.

### Exemplary Embodiment 1—Fabrication of Semiconductor Nanoparticles

In Exemplary embodiment 1, about 0.15 mmol of In(My)₃, about 0.075 mmol of Zn(My)₂ and about 0.1 mmol of tris(trimethylsilyl)phosphine [(TMS)₃P] were added into a glove box including about 1 mL of tris(trimethylsilyl)phosphine (TOP) and about 9 mL of 1-octadecene (ODE), and the mixture was heated to about 300° C. for about five minutes, while being stirred, to obtain an InZnP core (particle diameter about 2 nm). Next, 0.1 mmol of Al(O-i-Pr)₃ mixed with ODE at about 0.1 M was slowly added to the glove box to react at about 300° C. for about ten minutes, and thereby semiconductor nanoparticles having an InZnP core/Al₂O₃ shell structure (diameter: about 2.5 nm and shell thickness: about 0.3 nm) were obtained. In such an embodiment, in the semiconductor nanoparticles, the InZnP core has a conduction band of about −4.5 eV and a valence band of about −5.7 eV, the Al₂O₃ shell has a conduction band of about −1.3 eV, a valence band of about −9 eV, and a band gap of about 7.7 eV.

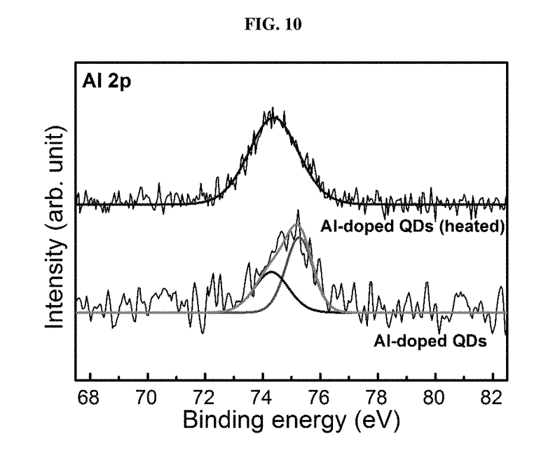

FIG. 10 is an XPS spectrum graph of semiconductor nanoparticles obtained in the above-described manner, and it may be appreciated that Al₂O₃ is formed in the semiconductor nanoparticles.

### Exemplary Embodiment 2—Fabrication of Semiconductor Nanoparticles

In Exemplary embodiment 2, about 0.15 mmol of In(My)₃, about 0.075 mmol of Zn(My)₂ and about 0.1 mmol of tris(trimethylsilyl)phosphine [(TMS)₃P] were added into a glove box including about 1 mL of tris(trimethylsilyl)phosphine (TOP) and about 9 mL of 1-octadecene (ODE), and the mixture was heated to about 300° C. for about five minutes, while being stirred, to obtain an InZnP core (particle diameter about 2 nm). Next, 0.1 mmol of Al(O-i-Pr)₃ mixed with ODE at about 0.1 M was slowly added to the glove box to react at about 300° C. for about ten minutes, and thereby semiconductor nanoparticles having an InZnP core/Al₂O₃ shell structure (Al₂O₃ shell thickness: about 0.5 nm) were obtained. Next, about 0.15 mmol of a Se precursor solution (Se-TOP), which was obtained by dissolving Se powder and S powder in TOP, was added into the glove box to react at about 300° C. for about twenty minutes to obtain semiconductor nanoparticles having an InZnP core/Al₂O₃ shell/ZnSeS shell structure (ZnSeS shell thickness: about 1 nm). Next, 1 mmol of Zn(St)₂ and 4 mmol of DDT were added to the glove box to react at about 300° C. for about one hour, and thus semiconductor nanoparticles having an InZnP core/Al₂O₃ shell/ZnSeS shell/ZnS shell structure (ZnS shell thickness: about 2 nm) were obtained. In such an embodiment, in the semiconductor nanoparticles, the InZnP core has a conduction band of about −4.5 eV and a valence band of about −5.7 eV, the Al₂O₃ shell has a conduction band of about −1.3 eV, a valence band of about −9 eV, and a band gap of about 7.7 eV, the ZnSeS shell has a conduction band of about −4.1 eV and a valence band of about −6.8 eV, and the ZnS shell has a conduction band of about −3.9 eV and a valence band of about −7.5 eV.

### Exemplary Embodiment 3—Fabrication of Semiconductor Nanoparticles

In Exemplary embodiment 3, about 0.15 mmol of In(My)₃ and about 0.1 mmol of tris(trimethylsilyl)phosphine [(TMS)₃P] were added into a glove box including about 1 mL of tris(trimethylsilyl)phosphine (TOP) and about 9 mL of 1-octadecene (ODE), and the mixture was heated to about 300° C. for about five minutes, while being stirred, to obtain an InP core (particle diameter: about 2 nm). Next, 0.1 mmol of Al(O-i-Pr)₃ mixed with ODE at about 0.1 M was slowly added to the glove box to react at about 300° C. for about ten minutes, and thereby semiconductor nanoparticles having an InP core/Al₂O₃ shell structure (diameter: about 2.5 nm and shell thickness: about 0.3 nm) were obtained. In such an embodiment, in the semiconductor nanoparticles, the InP core has a conduction band of about −4.5 eV and a valence band of about −5.7 eV, and the Al₂O₃ shell has a conduction band of about −1.3 eV, a valence band of about −9 eV, and a band gap of about 7.7 eV.

### Exemplary Embodiment 4—Fabrication of Semiconductor Nanoparticles

In Exemplary embodiment 4, about 0.15 mmol of In(My)₃ and about 0.1 mmol of tris(trimethylsilyl)phosphine [(TMS)₃P] were added into a glove box including about 1 mL of tris(trimethylsilyl)phosphine (TOP) and about 9 mL of 1-octadecene (ODE), and the mixture was heated to about 300° C. for about five minutes, while being stirred, to obtain an InP core (particle diameter: about 2 nm). Next, 0.1 mmol of Al(O-i-Pr)₃ mixed with ODE at about 0.1 M was slowly added to the glove box to react at about 300° C. for about ten minutes, and thereby semiconductor nanoparticles having an InP core/Al₂O₃ shell structure (Al₂O₃ shell thickness: about 0.3 nm) were obtained. Next, 1 mL of tris(trimethylsilyl)phosphine (TOP), about 9 mL of 1-octadecene (ODE), and about 0.075 mmol of Zn(My)₂ were added into the glove box, and about 0.15 mmol of a Se precursor solution (Se-TOP), which was obtained by dissolving Se powder and S powder in TOP, was added into the glove box to react at about 300° C. for about twenty minutes to obtain semiconductor nanoparticles having an InP core/Al₂O₃ shell/ZnSe shell structure (ZnSe shell thickness: about 1 nm). In such an embodiment, in the semiconductor nanoparticles, the InP core has a conduction band of about −4.5 eV and a valence band of about −5.7 eV, the Al₂O₃ shell has a conduction band of about −1.3 eV, a valence band of about −9 eV, and a band gap of 7.7 eV, and the ZnSe shell has a conduction band of about −3.9 eV and a valence band of about −7.5 eV.

### Comparative Example 1

In Comparative example 1, about 0.15 mmol of In(My)₃, about 0.075 mmol of Zn(My)₂ and about 0.1 mmol of tris(trimethylsilyl)phosphine [(TMS)₃P] were added into a glove box including about 1 mL of tris(trimethylsilyl)phosphine (TOP) and about 9 mL of 1-octadecene (ODE), and the mixture was heated to about 300° C. for about five minutes, while being stirred, to obtain an InZnP core (particle diameter about 2 nm). Next, about 0.15 mmol of a Se precursor solution (Se-TOP), which was obtained by dissolving Se powder and S powder in TOP, was added into the glove box to react at about 300° C. for about twenty minutes to obtain semiconductor nanoparticles having an InZnP core/ZnSeS shell structure (ZnSeS shell thickness: about 1 nm). In such an example, in the semiconductor nanoparticles, the InZnP core has a conduction band of about −4.5 eV and a valence band of about −5.7 eV, the ZnSeS shell has a conduction band of about −4.1 eV, a valence band of about −6.8 eV, and a band gap of about 2.7 eV.

### Comparative Example 2

In Comparative example 2, about 0.15 mmol of In(My)₃, about 0.075 mmol of Zn(My)₂ and about 0.1 mmol of tris(trimethylsilyl)phosphine [(TMS)₃P] were added into a glove box including about 1 mL of tris(trimethylsilyl)phosphine (TOP) and about 9 mL of 1-octadecene (ODE), and the mixture was heated to about 300° C. for about five minutes, while being stirred, to obtain an InZnP core (particle diameter about 2 nm). Next, 0.15 mmol of a Se precursor solution (Se-TOP), which was obtained by dissolving Se powder and S powder in TOP, was added into the glove box to react at about 300° C. for about twenty minutes to obtain semiconductor nanoparticles having an InZnP core/ZnSeS shell structure (ZnSeS shell thickness: about 1 nm). Next, 1 mmol of Zn(St)₂ and 4 mmol of DDT were added to the glove box to react at about 300° C. for about one hour to obtain semiconductor nanocrystals having an InZnP core/ZnSeS shell/ZnS shell structure (ZnS shell thickness: about 2 nm). In such an example, in the semiconductor nanoparticles, the InZnP core has a conduction band of about −4.5 eV and a valence band of about −6.7 eV, the ZnSeS shell has a conduction band of about −4.1 eV, a valence band of about −6.8 eV, and a band gap of about 2.7 eV, and the ZnS shell has a conduction band of about −3.9 eV and a valence band of about −7.5 eV.

### Comparative Example 3

In Comparative example 3, about 0.15 mmol of In(My)₃ and about 0.1 mmol of tris(trimethylsilyl)phosphine [(TMS)₃P] were added into a glove box including about 1 mL of tris(trimethylsilyl)phosphine (TOP) and about 9 mL of 1-octadecene (ODE), and the mixture was heated to about 300° C. for about five minutes, while being stirred, to obtain an InP core (particle diameter: about 2 nm). Next, about 1 mL of tris(trimethylsilyl)phosphine (TOP), about 9 mL of 1-octadecene (ODE), and about 0.075 mmol of Zn(My)₂ were added into the glove box, and then about 0.15 mmol of a Se precursor solution (Se-TOP), which was obtained by dissolving Se powder and S powder in TOP, was added into the glove box to react at about 300° C. for about 20 minutes to obtain semiconductor nanoparticles having an InP core/ZnSe shell structure (ZnSe shell thickness: about 1 nm). In such an example, in the semiconductor nanoparticles, the InP core has a conduction band of about −4.5 eV and a valence band of about −5.7 eV, and the ZnSe shell has a conduction band of about −3.9 eV, a valence band of about −7.5 eV, and a band gap of about 3.6 eV.

### Test Example 1

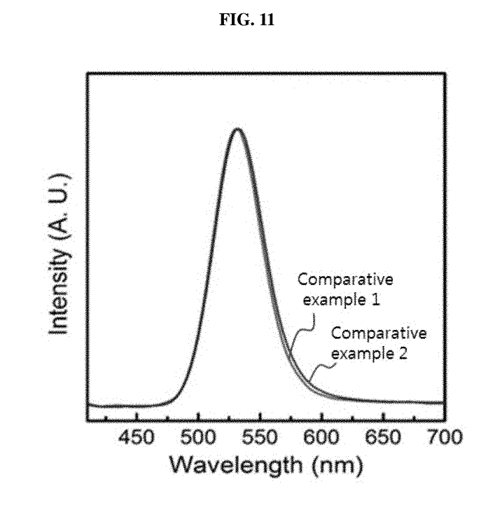

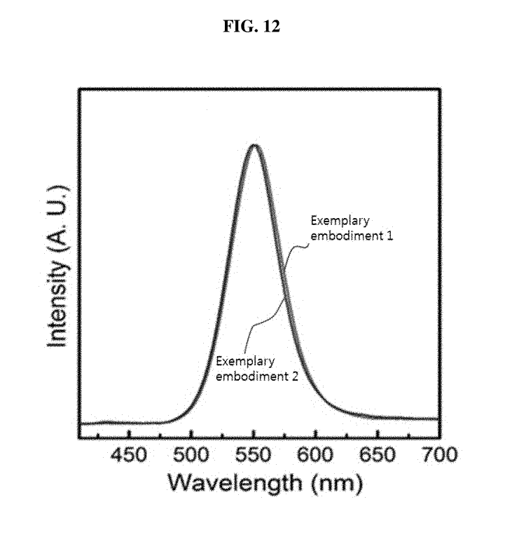

A photoluminescence (“PL”) peak, a full width half maximum (“FWHM”), and photoluminescence quantum efficiency (“PL QY”) of the semiconductor nanoparticles prepared in Exemplary embodiments 1 and 2 and Comparative examples 1 and 2 were measured, and the results are shown in Tables 1 and FIGS. 11-12.

TABLE 1

| | PL peak (nm) | FWHM (nm) | PL QY (%) |
|---|---|---|---|
| Exemplary embodiment 1 | 553.3 | 48.2 | 50 |
| Exemplary embodiment 2 | 551.1 | 47.6 | 64.4 |
| Comparative example 1 | 530.2 | 46.5 | 45.3 |
| Comparative example 2 | 530.2 | 48.1 | 62.3 |

As a result of the measurement, the semiconductor nanoparticles of Exemplary embodiment 1 have higher PL QY as compared with the semiconductor nanoparticles of Comparative example 1. In addition, the semiconductor nanoparticles of Exemplary embodiment 2 have higher photoluminescence quantum efficiency as compared with the semiconductor nanoparticles of Comparative example 2, and have a reduced FWHM as compared with the semiconductor nanoparticles of Exemplary embodiment 1.

### Test Example 2

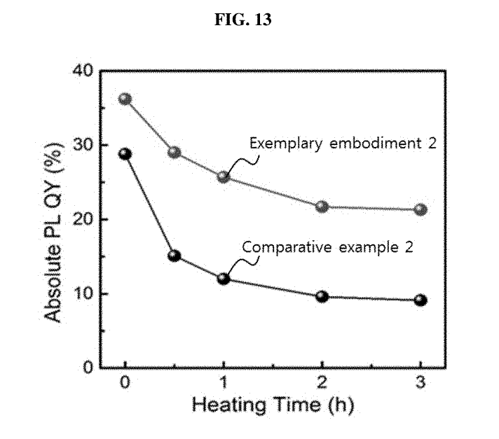

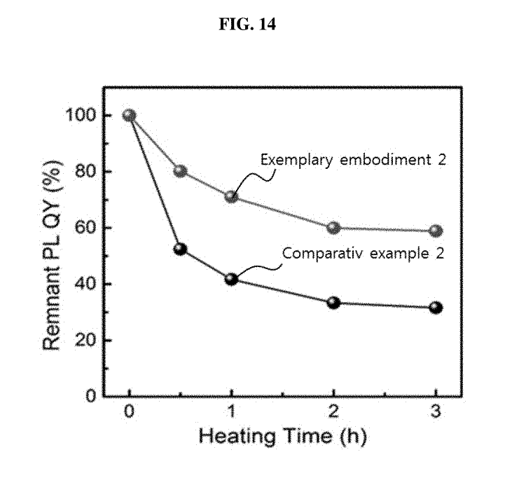

The thermal stability of the semiconductor nanoparticles prepared in Exemplary embodiment 2 and Comparative example 2 was measured, and the results are shown in FIGS. 13-14, respectively.

As may be seen from FIGS. 13-14, the semiconductor nanoparticles of Exemplary embodiment 2 have higher thermal stability than the semiconductor nanoparticles of Comparative example 2.

### Test Example 3

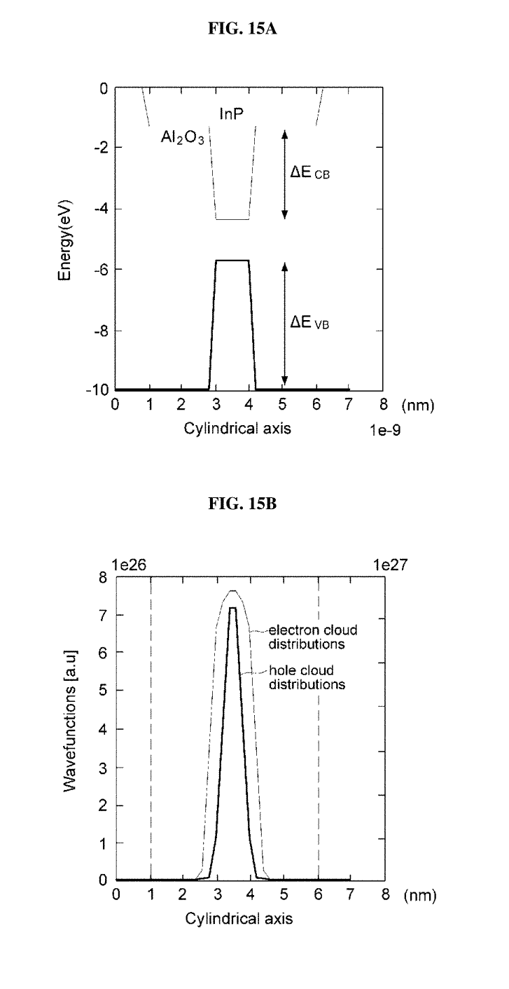

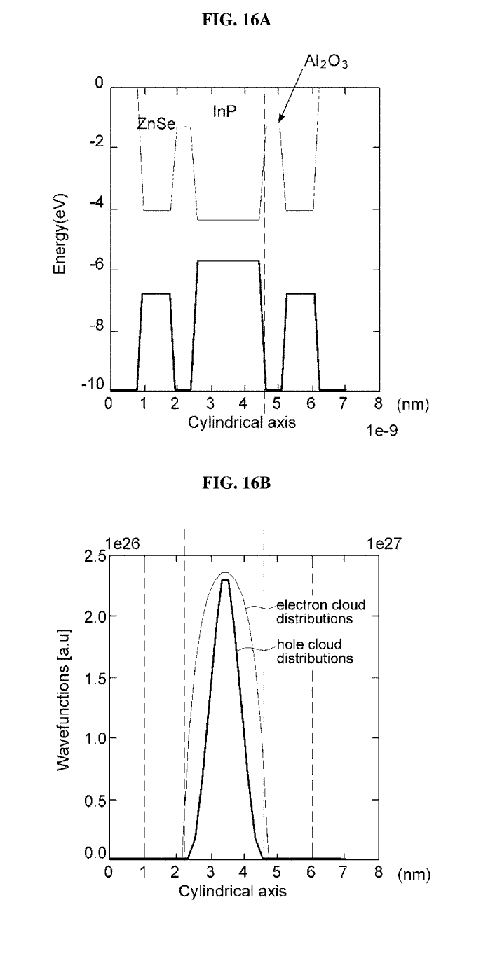

The energy band and the distributions of electron and hole clouds in the corresponding dimension of the semiconductor nanoparticles of Exemplary embodiments 3 and 4 and Comparative example 3 are shown in FIGS. 15A-15B, 16A-16B and 17A-17B, respectively.

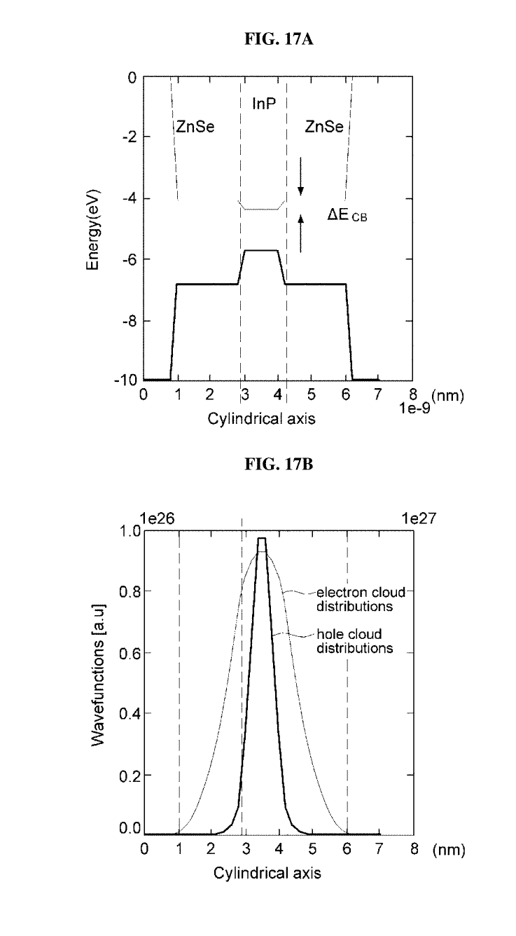

As may be seen from FIG. 15A and FIG. 16A, in the semiconductor nanoparticles of Exemplary embodiments 3 and 4, a conduction band offset between the InP core and the Al₂O₃ shell was about 3 eV, and a valence band offset therebetween was about 4.3 eV. On the other hand, in the semiconductor nanoparticles of Comparative example 3, a conduction band offset between the InP core and the ZnSe shell was about 0.3 eV, and a valence band offset therebetween was about 1.2 eV (see FIG. 17A).

In addition, it may be appreciated that electrons and holes in the semiconductor nanoparticles of Exemplary embodiments 3 and 4 were confined within the core, which is dissimilar to those in the semiconductor nanoparticles of Comparative example 3 (see FIG. 15B, FIG. 16B, and FIG. 17B).

As set forth hereinabove, the semiconductor nanoparticles according to one or more embodiments are excellent in optical and thermal stability and quantum efficiency. In addition, the display device according to one or more embodiments to which the semiconductor nanoparticles are applied is excellent in luminous efficiency and color reproducibility.

As used herein, the terms “use,” “using,” and “used” may be considered synonymous with the terms “utilize,” “utilizing,” and “utilized,” respectively. Also, the term “exemplary” is intended to refer to an example or illustration. The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, acts, operations, elements, and/or components, but do not preclude the presence or addition of one or more other features, integers, acts, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While the subject matter of the present disclosure has been illustrated and described with reference to the exemplary embodiments thereof, it will be apparent to those of ordinary skill in the art that various changes in form and detail may be formed thereto without departing from the spirit and scope of the present disclosure.

What is claimed is:

1. Semiconductor nanoparticles, a semiconductor nanoparticle of the semiconductor nanoparticles comprising:
a core comprising a compound semiconductor; and
a shell surrounding the core,
wherein the shell comprises: a metal oxide and/or a metalloid oxide having a bandgap of about 3.5 eV or more, and having a sum (ΔE_{CB}+ΔE_{VB}) of a conduction band offset (ΔE_{CB}) with the compound semiconductor comprised in the core and a valence band offset (ΔE_{VB}) with the compound semiconductor comprised in the core of about 3 eV or more.

2. The semiconductor nanoparticles of claim 1, wherein a ratio (t₁/r₁) of a thickness (t₁) of the shell to a radius (r₁) of the core is in a range of about 0.05 to about 5.

3. The semiconductor nanoparticles of claim 1, wherein the core and the shell have a lattice constant difference in a range of about −30% to about 30%.

4. The semiconductor nanoparticles of claim 1, wherein the shell has a content of the metal oxide and/or the metalloid oxide continuously increasing from a boundary with the core toward a surface of the shell.

5. The semiconductor nanoparticles of claim 1, wherein the semiconductor nanoparticle further comprises a second shell surrounding the shell, the second shell comprising a second compound semiconductor different from the compound semiconductor.

6. The semiconductor nanoparticles of claim 5, wherein the second shell has an energy band gap which is wider than an energy band gap of the core by about 0.5 eV to about 4 eV.

7. The semiconductor nanoparticles of claim 5, wherein a ratio [(t₁+t₂)/r₁] of a total thickness (t₁+t₂) of the shell and the second shell to the radius (r₁) of the core is in a range of about 0.3 to about 10, and
a ratio (t₁/t₂) of the thickness (t₁) of the shell to the thickness (t₂) of the second shell is in a range of about 0.1 to about 5.

8. The semiconductor nanoparticles of claim 5, wherein the semiconductor nanoparticle further comprises a third shell surrounding the second shell, the third shell comprising a metal oxide and/or a metalloid oxide that is the same as or different from the metal oxide and/or the metalloid oxide of the shell.

9. The semiconductor nanoparticles of claim 8, wherein a thickness (t₃) of the third shell is in a range of about 0.5 nm to about 5 nm.

10. The semiconductor nanoparticles of claim 1, wherein the semiconductor nanoparticle has a particle diameter in a range of about 1 nm to about 20 nm.

11. A display device comprising:
a display substrate;
a light amount control layer on the display substrate; and
a color conversion layer on the light amount control layer and comprising semiconductor nanoparticles,
wherein a semiconductor particle of the semiconductor nanoparticles comprises:
a core comprising a compound semiconductor; and
a shell surrounding the core and comprising a metal oxide and/or a metalloid oxide, and
the metal oxide and/or the metalloid oxide has a bandgap of about 3.5 eV or more, and has a sum (ΔE_{CB}+ΔE_{VB}) of a conduction band offset (ΔE_{CB}) with the compound semiconductor comprised in the core and a valence band offset (ΔE_{VB}) with the compound semiconductor comprised in the core of about 3 eV or more.

12. The display device of claim 11, wherein a ratio (t₁/r₁) of a thickness (t₁) of the shell to a radius (r₁) of the core is in a range of about 0.05 to about 5.

13. The display device of claim 11, further comprising a second shell surrounding the shell, the second shell comprising a second compound semiconductor different from the compound semiconductor.

14. The display device of claim 13, wherein a ratio [(t₁+t₂)/r₁] of a total thickness (t₁+t₂) of the shell and the second shell to the radius (r₁) of the core is in a range of about 0.3 to about 5, and
a ratio (t₁/t₂) of the thickness (t₁) of the shell to the thickness (t₂) of the second shell is in a range of about 0.1 to about 5.

15. The display device of claim 13, further comprising a third shell surrounding the second shell, the third shell comprising a metal oxide and/or a metalloid oxide that is the same as or different from the metal oxide and/or the metalloid oxide of the shell.

16. An organic light emitting display device comprising:
a base substrate;
an organic light emitting element on the base substrate; and
a color conversion layer on the organic light emitting element and comprising semiconductor nanoparticles,
wherein a semiconductor nanoparticle of the semiconductor nanoparticles comprises:
a core comprising a compound semiconductor; and
a shell surrounding the core and comprising a metal oxide and/or a metalloid oxide, and
the metal oxide and/or the metalloid oxide has a bandgap of about 3.5 eV or more, and has a sum (ΔE_{CB}+ΔE_{VB}) of a conduction band offset (ΔE_{CB}) with the compound semiconductor comprised in the core and a valence band offset (ΔE_{VB}) with the compound semiconductor comprised in the core of about 3 eV or more.

17. The organic light emitting display device of claim 16, wherein a ratio (t₁/r₁) of a thickness (t₁) of the shell to a radius (r₁) of the core is in a range of about 0.05 to about 5.

18. The organic light emitting display device of claim 16, further comprising a second shell surrounding the shell, the second shell comprising a second compound semiconductor different from the compound semiconductor.

19. The organic light emitting display device of claim 18, wherein a ratio [(t₁+t₂)/r₁] of a total thickness (t₁+t₂) of the shell and the second shell to the radius (r₁) of the core is in a range of about 0.3 to about 10, and
a ratio (t/t₂) of the thickness (t₁) of the shell to the thickness (t₂) of the second shell is in a range of about 0.1 to about 5.

20. The organic light emitting display device of claim 18, further comprising a third shell surrounding the second shell, the third shell comprising a metal oxide and/or a metalloid oxide that is the same as or different from the metal oxide and/or the metalloid oxide of the shell.
